(19) United States
(12) Patent Application Publication
(10) Pub. No.: US 2010/0271856 A1
(43) Pub. Date: Oct. 28, 2010

(54) SEMICONDUCTOR MEMORY DEVICE HAVING HIERARCHICALLY-CONSTRUCTED I/O LINES

(75) Inventor: Hisashi YAMAZAKI, Tokyo (JP)

Correspondence Address: YOUNG & THOMPSON, 209 Madison Street, Suite 500, Alexandria, VA, 22314, US

(73) Assignee: ELPIDAMEMORY INC., TOKYO (JP)

(21) Appl. No.: 12/489,756

(22) Filed: Jun. 23, 2009

(30) Foreign Application Priority Data
Apr. 28, 2009 (JP) 2009-109655

(51) Int. Cl. G11C 5/02; G11C 8/00; G11C 5/06

(52) U.S. Cl. 365/51; 365/230.03; 365/63

(57) ABSTRACT

To provide main I/O lines(MIOX) arranged along an X direction; a plurality of I/O nodes(ND) arranged along the X direction; an amplifier circuit area(AMPA) including a plurality of amplifier circuits(AMP); a plurality of main I/O lines(MIOY) arranged along a Y direction, which respectively connect each of the main I/O lines(MIOX) and each of the corresponding I/O nodes(ND). Among the main I/O lines(MIOY) allocated to the amplifier circuits different from one another, that having a longer wire length is connected more closely to a center of the corresponding main I/O line(MIOX); and that having a shorter wire length is connected more closely to an end of the corresponding main I/O line(MIOX). Accordingly, the difference in wire length for each signal route becomes smaller, and also the wire length of the longest wire route is reduced.

### BACKGROUND OF THE INVENTION

1. Field of the Invention

The present invention relates to a semiconductor memory device, and, more particularly relates to a semiconductor memory device having hierarchically-constructed I/O lines.

2. Description of Related Art

Semiconductor memory devices represented by DRAM (Dynamic Random Access Memory) include a large number of hierarchically-constructed I/O lines. For example, in FIG. 5 of Japanese Patent Application Laid-open No. 2001-94069 (hereinafter called “patent document 1”), there is described a configuration such that a pair of local data buses LDP formed on a sense amplifier block SB and a pair of global data buses GDP connected to the pair of local data buses LDP via a bus connect line 20 are provided, and ends of the pair of global data buses GDP are connected to a pre-amplifier/write driver 3.

However, in the semiconductor memory device described in the patent document 1, there is a problem that depending on a position of the pair of local data buses LDP, the total wire length of the corresponding bus connect line 20 and the pair of global data buses GDP greatly differs. More specifically, the pair of local data buses LDP further away from the pre-amplifier/write driver 3 has a longer total wire length of the corresponding bus connect line 20 and the pair of global data buses GDP. Thus, when a route length to the pre-amplifier/write driver 3 differs depending on each pair of local data buses LDP, an operation of the semiconductor memory device is rate-controlled by a delay time caused by the longest wire length.

Meanwhile, in Japanese Patent Application Laid-open No. H11-97633 (hereinafter called “patent document 2”), there is disclosed rendering uniform wire lengths of I/O buses that connect a main amplifier and a bonding pad. Accordingly, a delay time between the main amplifier and the bonding pad can be rendered almost constant. However, rendering constant the delay time is realized only between the main amplifier and the bonding pad, that is, a circuit portion on the outside (on a pad side) of the main amplifier. Like the patent document 1, the difference in delay time in a circuit portion on the inside (on a memory cell array side) of the main amplifier cannot be reduced.

Thus, in the conventional semiconductor memory device, there is a problem that, as viewed from a main amplifier, the difference in wire length on a memory cell array side is large, and thus, due to a delay time caused by the longest wire, access speed is rate-controlled.

### SUMMARY

The present invention seeks to solve one or more of the above problems, or to improve upon those problems at least in part.

In one embodiment, there is provided a semiconductor memory device that includes a plurality of first I/O lines arranged along a first direction; a plurality of I/O nodes arranged along the first direction; an amplifier circuit area including a plurality of amplifier circuits provided respectively corresponding to one or more of the I/O nodes; and a plurality of second I/O lines which are arranged along a second direction orthogonal to the first direction, and respectively connect each of the first I/O lines and each of the corresponding I/O nodes, wherein among the second I/O lines allocated to the amplifier circuits different from one another, the second I/O line having a longer wire length is connected more closely to a center of the corresponding first I/O line, and the second I/O line having a shorter wire length is connected more closely to an end of the corresponding first I/O line.

According to the present invention, among second I/O lines, a line with a longer wire length is connected more centrally to the first I/O line, and thus, as compared to conventional semiconductor memory devices, the difference in wire length for each signal route becomes smaller and also a wire length of the longest wire route is reduced. As a result, access speed can be increased.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plan view showing a layout of a semiconductor memory device according to an embodiment of the present invention;

FIG. 2 is a plan view showing a layout of the memory mats MAT included in each hank;

FIG. 3 is a circuit diagram of the memory cells MC;

FIG. 4 is a schematic diagram showing one example of a right-half area of the bank A in an enlarged manner, and shows the layout in the first embodiment;

FIG. 5 is a plan view showing a layout of a comparative example;

FIG. 6 is a schematic diagram showing another example of a right-half area of the bank A in an enlarged manner, and shows the layout in the first embodiment;

FIG. 7 is a schematic diagram showing a right-half area of the bank A in an enlarged manner, and shows the layout in the second embodiment; and

FIG. 8 is another plan view showing a layout of the comparative example.

### DETAILED DESCRIPTION OF THE EMBODIMENTS

Preferred embodiments of the present invention will be explained below in detail with reference to the accompanying drawings.

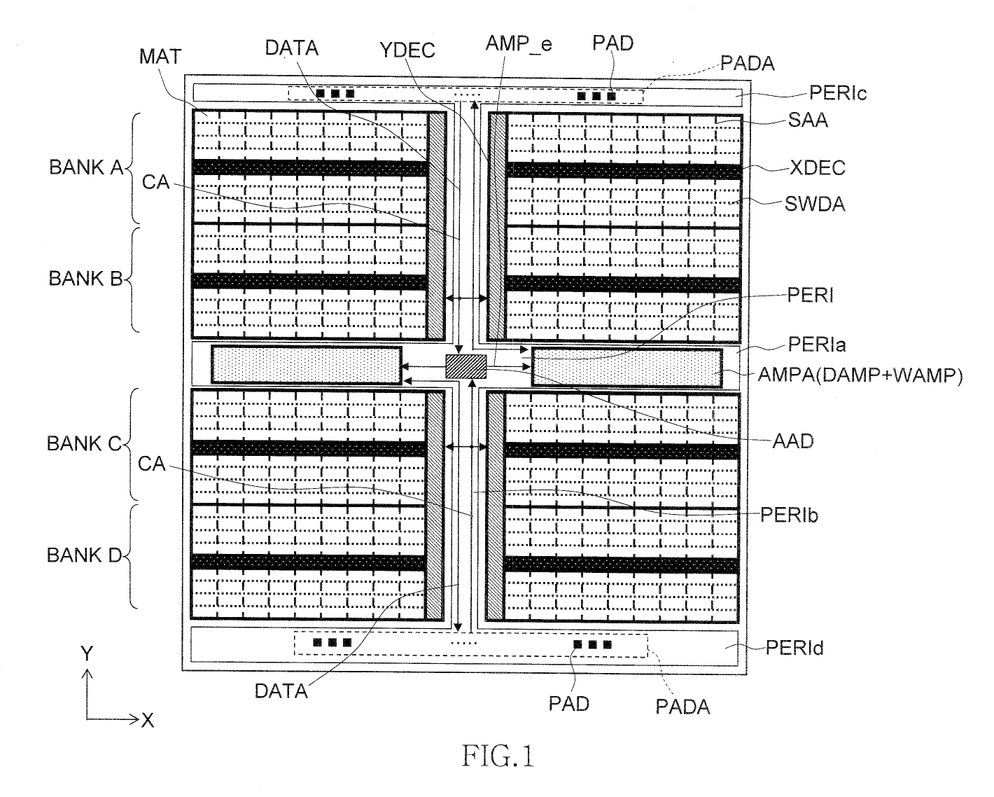

FIG. 1 is a plan view showing a layout of a semiconductor memory device according to a preferred embodiment of the present invention.

As shown in FIG. 1, the semiconductor memory device according to the embodiment includes four banks A to D, and peripheral circuit areas PERI. While the four banks A to D are arranged along a Y direction in this embodiment, the layout of the semiconductor memory device according to the present invention is not limited to thereto.

Each of the banks includes a plurality of memory mats MAT, an X decoder circuit XDEC, a Y decoder circuit YDEC, a plurality of sense amplifier arrays SAA, and a plurality of sub-word driver arrays SWDA. In the embodiment, each bank is divided into two in an X direction, and in the divided areas, each Y decoder circuit YDEC extending along the Y direction is arranged. Each bank is divided into two also in the Y direction, and in the divided areas, each X decoder circuit XDEC extending along the X direction is arranged. The present invention is not limited to such a layout. Detailed configurations of the bank will be described later.

Each of the peripheral circuit area PERI includes a circuit area PERIa extending along the X direction between the bank B and the bank C, a circuit area PERIb extending along the Y direction in a separated area in the X direction of the banks A to D, a circuit area PERIc extending along the X direction between the bank A and the end of a chip, and a circuit area PERId extending along the X direction between the bank D and the end of the chip.

Among the peripheral circuit areas PERI, in the circuit area PERIa, an amplifier area AMPA in which a data amplifier circuit DAMP and a write amplifier circuit WAMP are arranged, and an amplifier address decoder circuit AAD are arranged. Among the peripheral circuit areas PERI, in the circuit areas PERIc and PERId, a pad area PADA including a plurality of pads PAD that exchange a signal with outside is provided.

The pads PAD include a plurality of command-use pads supplied with a command signal for controlling an operation of the semiconductor memory device from outside, an address-use pad supplied with an address signal for designating a predetermined memory cell of the semiconductor memory device from outside, and a data pad to which data to be written in a memory cell is inputted from outside or from which the data in the memory cell is outputted. Among these pads, the data pad is connected to the amplifier area AMPA. Accordingly, input/output data DATA is transmitted between each pad PAD and the amplifier area AMPA.

Further, the address signal inputted from the address pad is supplied to the X decoder circuit XDEC, the Y decoder circuit YDEC, and the amplifier address decoder circuit AAD. Upon reception of a column address CA inputted from the address pad, the amplifier address decoder circuit AAD outputs activating signals AMP_e for activating the data amplifier circuit DAMP or write amplifier circuit WAMP corresponding to the address. More specifically, in an operation mode for writing the data in the semiconductor memory device (a write operation), the write amplifier WAMP corresponding to the designated column address CA is activated, and in an operation mode for reading the data from the semiconductor memory device (a read operation), the data amplifier DAMP corresponding to the designated column address CA is activated.

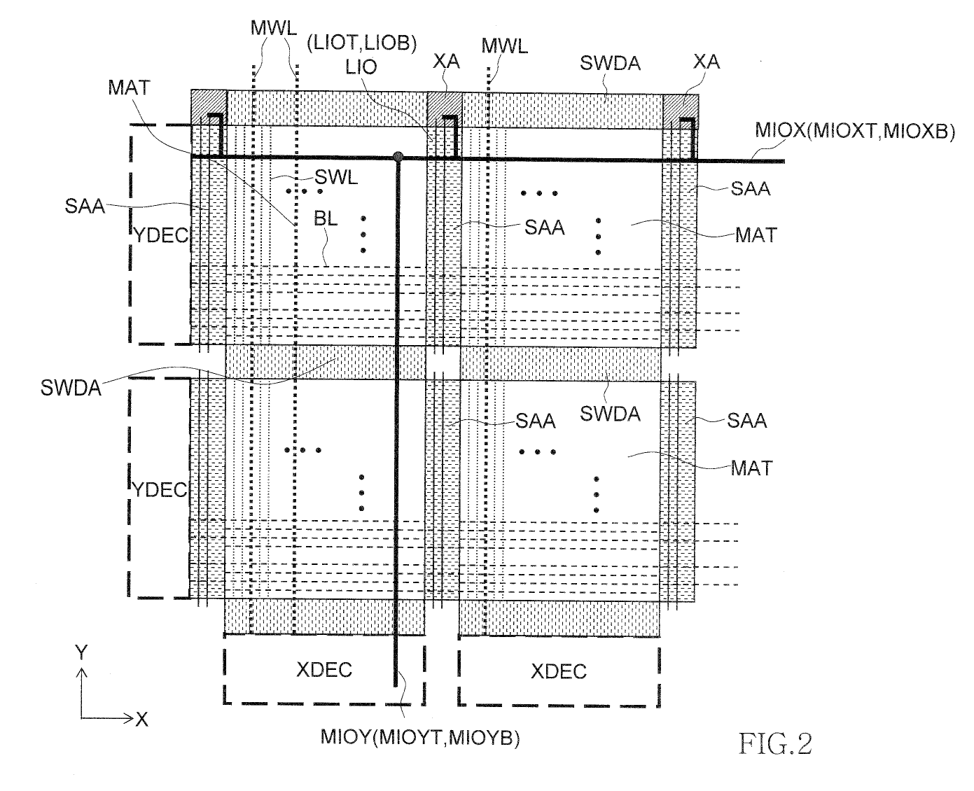

FIG. 2 is a plan view showing a layout of the memory mats MAT included in each bank.

As shown in FIG. 2, each bank includes the memory mats MAT arranged in a matrix in the X direction and the Y direction. Between the memory mats MAT adjacent to the X direction, the sense amplifier arrays SAA are respectively arranged, and between the memory mats MAT adjacent to the Y direction, the sub-word driver arrays SWDA are respectively arranged. The sense amplifier arrays SAA include a plurality of sense amplifiers, and the sub-word driver arrays SWDA include a plurality of sub-word drivers.

Each sub-word driver is a circuit that drives a sub word line SWL extending along the Y direction, and selects the sub word line SWL based on a row address inputted via each address pad. The sub-word driver is connected with a main word line MWL driven by the X decoder circuit XDEC Each sense amplifier is a circuit connected to a pair of bit lines BL extending along the X direction, and serves a role for amplifying a potential difference occurring in the pair of bit lines BL. At intersection points between the sub word lines SWL and the bit lines BL, memory cells MC are respectively arranged.

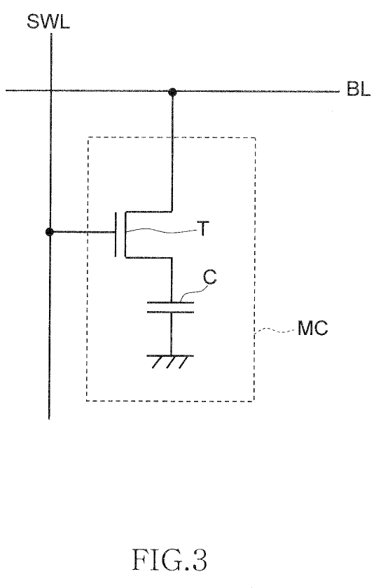

FIG. 3 is a circuit diagram of the memory cells MC.

As shown in FIG. 3, the memory cell MC in this embodiment is a DRAM cell, and has a configuration in which one cell transistor T and one cell capacitor C are connected in series. A gate electrode of the cell transistor T is connected to the corresponding sub word line SWL, and one of a source and a drain of the cell transistor T is connected to the corresponding bit line BL. By such a configuration, when the corresponding sub word line SWL is selected, the cell transistor T is turned on. Accordingly, the corresponding bit line BL arid cell capacitor C are connected. As a result, it becomes possible to transmit and receive a charge to and from the cell capacitor C.

Referring back to FIG. 2, at the upper part of the sense amplifier array SAA, local I/O lines LIO extending along the Y direction are provided. The local I/O lines LIO are provided for each sense amplifier array SAA, and connected to any one of the sense amplifiers included in the corresponding sense amplifier arrays SAA, respectively, via column switches (not shown). A part of the column address designates to which sense amplifiers each local I/O line LIO is connected. Based on the column address, the Y decoder circuit YDEC controls the column switch. Each local I/O line LIO is composed of a pair of LIOT and LIOB that are complementary to each other.

Further, at the upper part of the memory mats MAT, a first main I/O line MIOX extending along the X direction is provided. In FIG. 2, the first main I/O line MIOX is indicated by a single line. However, in a strict sense, the first main I/O line MIOX is composed of a pair of MIOXT and MIOXB that are complementary to each other. MIOXT is a wire connected to LIOT, and MIOXB is a wire connected to LIOB. In the following descriptions, the “first main I/O line MIOX” represents the pair of MIOXT and MIOXB.

In addition, at the upper part of the memory mats MAT, a second main I/O line MIOY extending along the Y direction is provided. In FIG. 2, the second main I/O line MIOY is also indicated by a single line. However, in a strict sense, the second main I/O line MIOY is composed of a pair of MIOYT and MIOYB that are complementary to each other. MIOYT is a wire connected to MIOXT, and MIOYB is a wire connected to MIOXB. More specifically, one end of the second main I/O line MIOYT is connected to the corresponding first main I/O line MIOXT, and the other end of the second main I/O line MIOYT is connected to an I/O node described later. Likewise, one end of the second main I/O line MIOYB is connected to the corresponding first main I/O line MIOXB, and the other end of the second main I/O line MIOYB is connected to the I/O node. In the following descriptions, the “second main I/O line MIOY” represents the pair of MIOYT and MIOYB.

Although not particularly limited, these I/O lines are preferably formed on wire layers different from one another. For example, when a wire layer on which the bit line BL is formed is defined as a metal wire layer M1 of a first layer, the local I/O line LIO can be formed on a metal wire layer M2 of a second layer, the first main I/O line MIOX can be formed on a metal wire layer M3 of a third layer, and the second main I/O line MIOY can be formed on a metal wire layer M4 of a fourth layer.

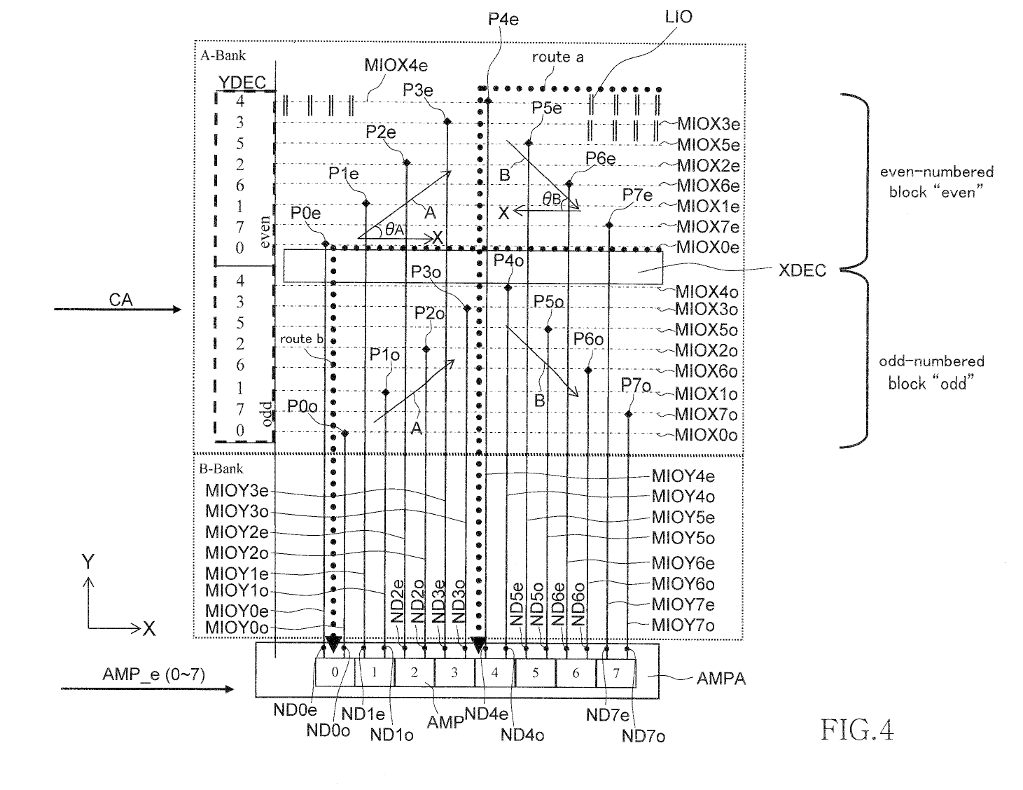

FIG. 4 is a schematic diagram showing a right-half area of the bank A in an enlarged manner, and shows the layout in the first embodiment.

As shown in FIG. 4, in the first embodiment, each bank is separated in an even-numbered block “even” and an odd-numbered block “odd”. These blocks are arranged along the Y direction. Between the even-numbered block “even” and the odd-numbered block “odd”, the X decoder circuit XDEC is arranged. The even-numbered block “even” and the odd-numbered block “odd” are assigned with the same row address and column address. Upon reading, the memory cell designated by the row address and the column address is selected from the blocks of each of the even-numbered block “even” and the odd-numbered block “odd”. Data held in the two memory cells are outputted in parallel from the read amplifier, serially converted by a predetermined output unit (not shown), and outputted to the outside of the semiconductor memory device. For example, in synchronism with a rise of a clock signal, the data read from the odd-numbered block “odd” is outputted, and in synchronism with a fall of the clock signal, the data read from the even-numbered block “even” is outputted. Upon writing, the data serially inputted from the outside of the semiconductor memory device are parallel-converted by a predetermined output unit (not shown) and via the write amplifier, the individual data are written in the memory cells designated by the row address and the column address in each of the even-numbered block “even” and odd-numbered block “odd”.

As one example, in the first embodiment, eight first main I/O lines MIOX are provided in each of the even-numbered block “even” and the odd-numbered block “odd”. As a result, the eight second main I/O lines MIOY are provided in each of the even-numbered block “even” and the odd-numbered block “odd”. The second main I/O lines MIOY are connected to the corresponding amplifier circuits AMP via the I/O node ND, respectively. In this case, the respective amplifier circuits AMP are circuit blocks each including the data amplifier circuit DAMP and the write amplifier circuit WAMP.

To describe more specifically, the amplifier circuits AMP are arranged along the X direction, and numbers (column addresses) of 0 to 7 (in order from its end) are allocated, respectively. For each number, the amplifier circuit for the even-numbered block “even” and the amplifier circuit for the odd-numbered block “odd” are arranged. Each amplifier circuit AMP is a set of amplifier circuits, that is, the amplifier circuit for the even-numbered block “even” and the amplifier circuit for the odd-numbered block “odd”. Accordingly, in the first embodiment, the number (═N) of amplifier circuits AMP to be included in the single amplifier area AMPA is 8 for the even-numbered block “even” and the odd-numbered block “odd” each. The amplifier circuits AMP0 to AMP7 are activated by the corresponding activating signals AMP_e0 to AMP_e7, respectively. As described above, the activating signals AMP_e are column address signals supplied from the amplifier address decoder circuit AAD. Note that N is not limited in value to these numbers in the present invention, and can be any integer equal to or more than four.

As shown in FIG. 4, the respective amplifier circuits AMP are connected with the two main I/O lines MIOY via the I/O node ND. Among the two lines, one line is the second main I/O line MIOY corresponding to the even-numbered block “even”, and the other line is the second main I/O line MIOY corresponding to the odd-numbered block “odd”. More specifically, the respective amplifier circuits AMPk (k=0 to 7) are connected to the second main I/O lines MIOYke via the I/O nodes NDke, and connected to the second main I/O lines MIOYko via the I/O nodes NDko. In the first embodiment, the I/O nodes ND are arranged in the amplifier area AMPA.

The first main I/O lines MIOX also are allocated with the same numbers as those of the corresponding amplifier circuits AMP and second main I/O lines MIOY. Accordingly, the second main I/O lines MIOYke are connected with the first main I/O lines MIOXke, and the second main I/O lines MIOYko are connected with the first main I/O lines MIOXko.

In this case, when the corresponding numbers k are also given to the intersection points P to which the first main I/O lines MIOX and the second main I/O lines MIOY are connected, intersection points P0 to P3 (P0e to P3e, P0o to P3o) to which 0 to (N/2)−1 are allocated are arranged along an A direction different from the X direction and the Y direction, and intersection points P4 to P7 (P4e to P7e, P4o to P7o) to which N/2 to N−1 are allocated are arranged along a B direction different from the X, Y, and A directions.

When the X direction is defined as horizontal, as shown in FIG. 4, the A direction is a right-up direction and the B direction is a left-up direction. An angle θA formed between the A direction and the X direction and an angle θB formed between the B direction and the X direction are equal to each other.

Because of such an arrangement, the amplifier circuits AMP and the second main I/O lines MIOY are provided along in order numbered in the X direction while the first main I/O lines MIOX are not provided along in order numbered in the Y direction. Specifically, between the i^{th} (i is an integer from 0 to N−2, but excludes (N/2)−1) first main I/O line MIOX (MIOXie, MIOXio) and the i+1^{th} first main I/O line MIOX (MIOXi+−1e, MIOXio−1o), a different first main I/O line MIOX is arranged. In this case, when the number of the different first main I/O line is j, a relation of i+j=N−1 is established.

Each of the first main I/O lines MIOX is configured to be connectable to any one of the local I/O lines LIO arranged along the Y direction. In this case, the local I/O lines LIO corresponding to the same first main I/O line MIOX are arranged at a substantially equal interval in the X direction.

As a result, the second main I/O lines MIOY longer in wire length, which are allocated to the amplifier circuits AMP different from one another, are connected more closely to the center of the corresponding first main I/O lines MIOX, and those shorter in wire length are connected more closely to the end of the corresponding first main I/O lines MIOX. Accordingly, the difference in the total wire length between the signal routes is reduced, and also the wire length of the longest wire route is reduced. The wire length of the local I/O lines LIO is sufficiently shorter than those of the first main I/O lines MIOX and the second main I/O lines MIOY, and thus the difference in the total wire length can be regarded as the difference in signal route length front a connected location between the local I/O lines LIO and the first main I/O lines MIOX to the amplifier circuits AMP.

More specifically, as the even-numbered block “even” is focused, the longest route that undergoes the first main I/O line MIOX4e furthest from the I/O node is a route “a” shown in FIG. 4, and the longest route that undergoes the first main I/O line MIOX0e closest from the I/O node is a route “b” shown in FIG. 4. In this way, when the wire length of the second main I/O line MIOY is long, the longest route length of the first main I/O line MIOX is shorter, and when the wire length of the second main I/O line MIOY is short, the longest route length of the first main I/O line MIOX is longer. This reduces the difference between a far end and a near end.

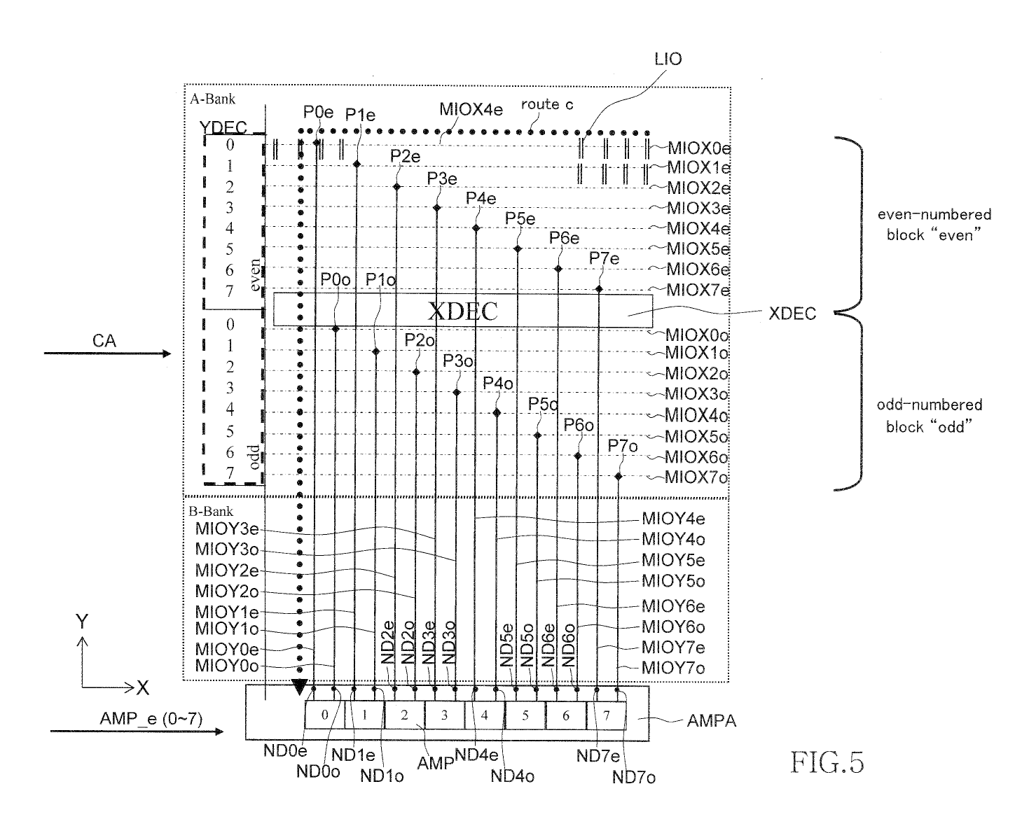

FIG. 5 is a plan view showing a layout of a comparative example.

In the comparative example shown in FIG. 5, unlike the layout shown in FIG. 4, the first main I/O lines MIOX also are provided along in order numbered in the Y direction. As a result, as the even-numbered block “even” is focused, the longest route that undergoes the first main I/O line MIOX0e furthest from the I/O node is a route “c” shown in FIG. 5, which is a route significantly longer than the route “a” shown in FIG. 4.

More specifically, when the length of the first main I/O line MIOX is x (max) and that of the second main I/O line MIOY is y (max), the wire length of the route “c” is defined as x(max)+y(max). On the other hand, in the semiconductor memory device according to the first embodiment shown in FIG. 4, the wire length of the route “a” is x/2(max)+y (max), which is shorter by about x/2(max) than the route “c” shown in FIG. 5. In the semiconductor memory device according to the first embodiment shown in FIG. 4, which of the routes the wire length is the longest depends on a ratio of x to y, that is, the shape of each bank and other conditions. However, whatever the shape it can be, the wire length of the route “a” is shorter by about ½(max) than the layout shown in FIG. 5. Thereby, according to the semiconductor memory device of the first embodiment, it becomes possible to increase the access speed.

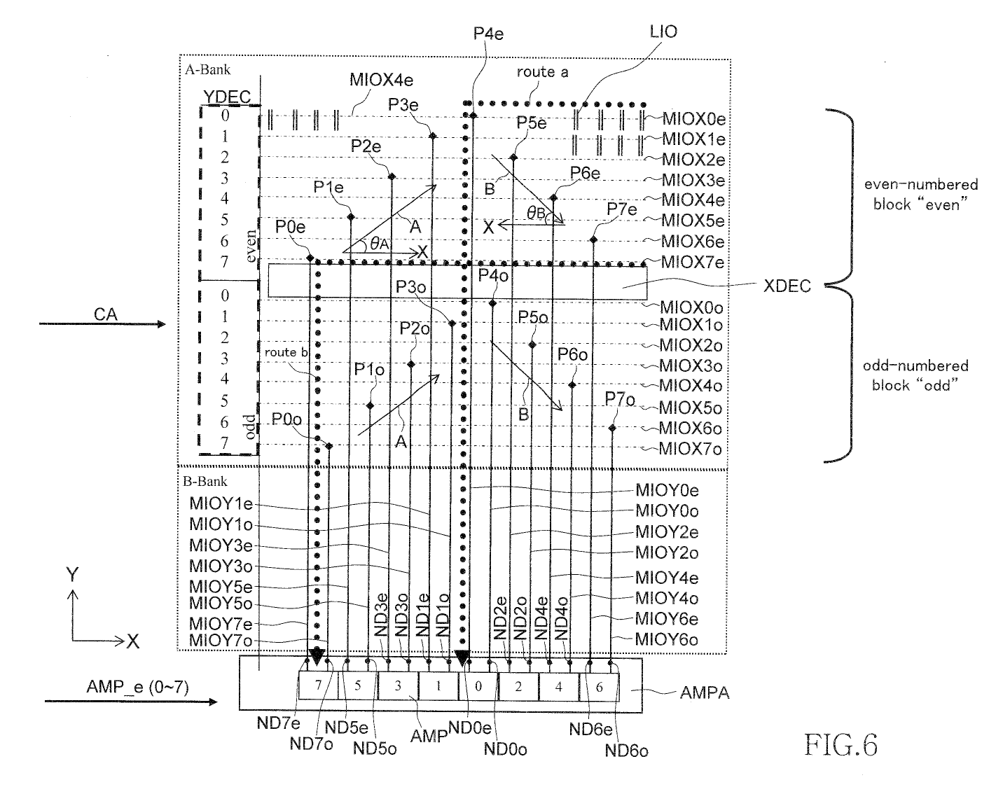

In the first embodiment, the numbers allocated to the amplifier circuits AMP are provided in order from 0 to 7 from the end. However, the numbers allocated to the first main I/O lines MIOX can be provided in order from 0 to 7 from the end In this case, as shown in FIG. 6, the amplifier circuits AMP1, 3, 5, and 7 can be arranged in this order on the left side from the center of FIG. 6, and the amplifier circuits AMP0, 2, 4, and 6 can be arranged in this order on the right side from the center of FIG. 6.

A second embodiment of the present invention is described next.

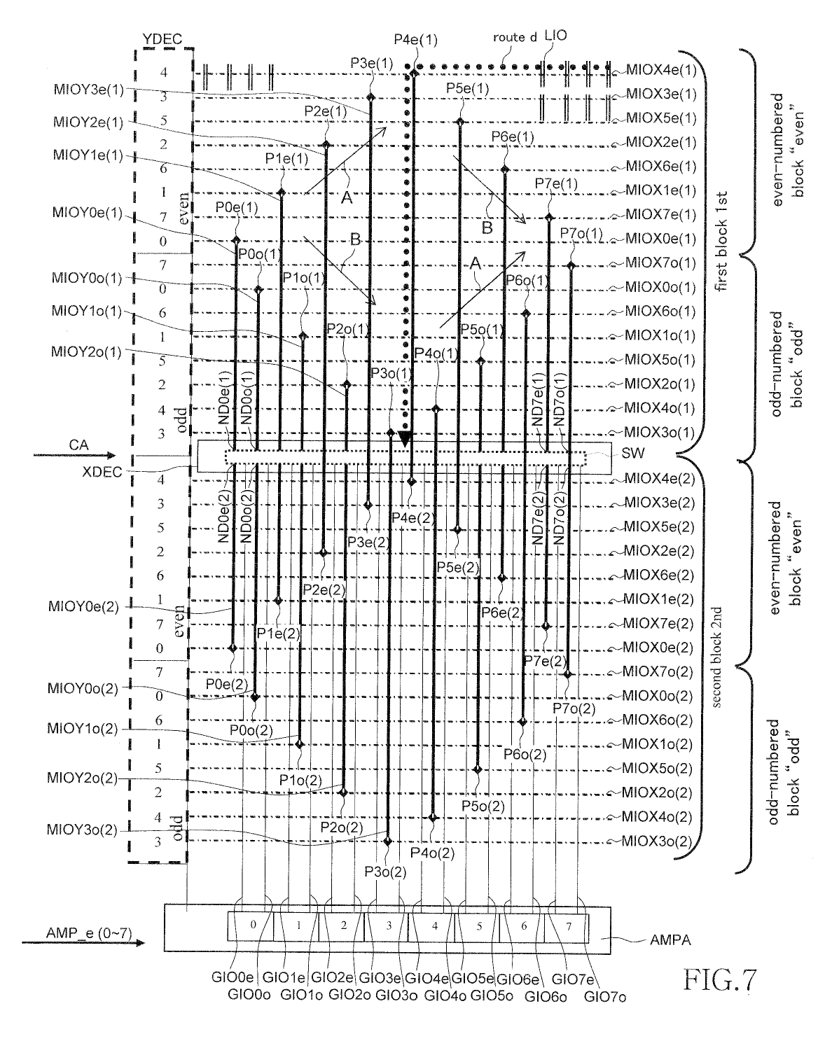

FIG. 7 is a schematic diagram showing a right-half area of the bank A in an enlarged manner, and shows the layout in the second embodiment.

In the second embodiment, each bank is divided into a first block 1st and a second block 2nd. The blocks 1st and 2nd are arranged along the Y direction, and between the blocks, a switching circuit SW extending along the X direction is arranged The switching circuit SW is arranged in a circuit area in which the X decoder circuit XDEC is provided. Each block is further separated into an even-numbered sub-block and an odd-numbered sub-block. In FIG. 7, (1) is attached to numerals of elements belonging to the first block 1st, and (2) is attached to numerals of elements belonging to the second block 2nd.

As shown in FIG. 7, the address allocation of the first main I/O lines MIOX (1) in the even-numbered sub-block “even” included in the first block 1st and the arrangement of the intersection points P(1) are the same as those in the first embodiment shown in FIG. 4. On the contrary, the address allocation of the first main I/O lines MIOX (1) in the odd-numbered sub-block “odd” included in the first block 1st and the arrangement of the intersection points P(1) are opposite to those in the first embodiment shown in FIG. 4.

That is, in the odd-numbered sub-block “odd” included in the first block 1st, the intersection points P0o(1) to P3o(1) allocated with 0 to (N/2)−1 are arranged along the B direction, and the intersection points P4o(1) to P7o(1) allocated with N/2 to N−1 are arranged along the A direction. As a result, in the odd-numbered sub-blocks “odd” included in the first block 1st, the second main I/O lines MIOY (1) longer in wire length, which are allocated to the amplifier circuits AMP different from one another, are connected more closely to the end of the corresponding first main I/O lines MIOX, and those shorter in wire length are connected more closely to the center of the corresponding first main I/O lines MIOX. In the second embodiment, the I/O nodes are arranged in the switching circuit SW.

The layout in the second block 2nd is opposite to that in the first block 1st. That is, the address allocation of the first main I/O lines MIOX (2) in the odd-numbered sub-block “odd” included in the second block 2nd and the arrangement of the intersection points P(2) are the same as those in the first embodiment shown in FIG. 4. On the other hand, the address allocation of the first main I/O lines MIOX (2) in the even-numbered sub-block “even” included in the second block 2nd and the arrangement of the intersection points P(2) are opposite to those in the first embodiment shown in FIG. 4.

In the second embodiment, all the second main I/O lines MIOY are once connected to the switching circuit SW. The switching circuit SW selects one of the second main I/O lines MIOY(1) and MIOY(2) based on a predetermined 1 bit of the column address. This means that the block selection is distinguished by a predetermined bit of the column address. The selected side is connected to the corresponding amplifier circuit AMP via each global I/O line GIO (GIO0e to 7e, GIO0o to 7o). The global I/O lines GIO are 16 wires extending along the Y direction, and are equal in length to one another. In FIG. 7, the global I/O lines GIO are indicated by a single line. However, in a strict sense, each global I/O line GIO is a pair of GIOT and GIOB that are complementary to each other. GIOT is a wire connected to MIOYT and GIOB is a wire connected to MIOYB. In the following descriptions, the “global I/O line GIO” represents the pair of GIOT and GIOB.

According to such a configuration, the total wire length of the two second main I/O lines MIOY corresponding to the same global I/O line GIO is constant.

In the second embodiment, the main I/O lines MIO in the sub-blocks (even in the 1st and odd in the 2nd) arranged on a side away from the switching circuit SW in each of the blocks are more preferentially arranged than the sub-blocks (odd in the 1st and even in the 2nd) arranged on a side closer to the switching circuit SW. The reason for this is that in a bank configuration shown in FIG. 7, there is a route that is the longest wire in the sub-blocks (even in the 1st and odd in the 2nd) arranged on the side away from the switching circuit SW.

In this way, in the second embodiment, when it is so configured that each bank is divided into first and second blocks and these blocks are selected by the switching circuit SW, the layout of the intersection points P in the even-numbered sub-blocks “even” and the layout of the intersection points P in the odd-numbered sub-blocks “odd” are in a mirror arrangement, where a borderline therebetween is assumed as a symmetrical axis. Accordingly, similarly to the first embodiment, it becomes possible to reduce the difference between a far end and a near end.

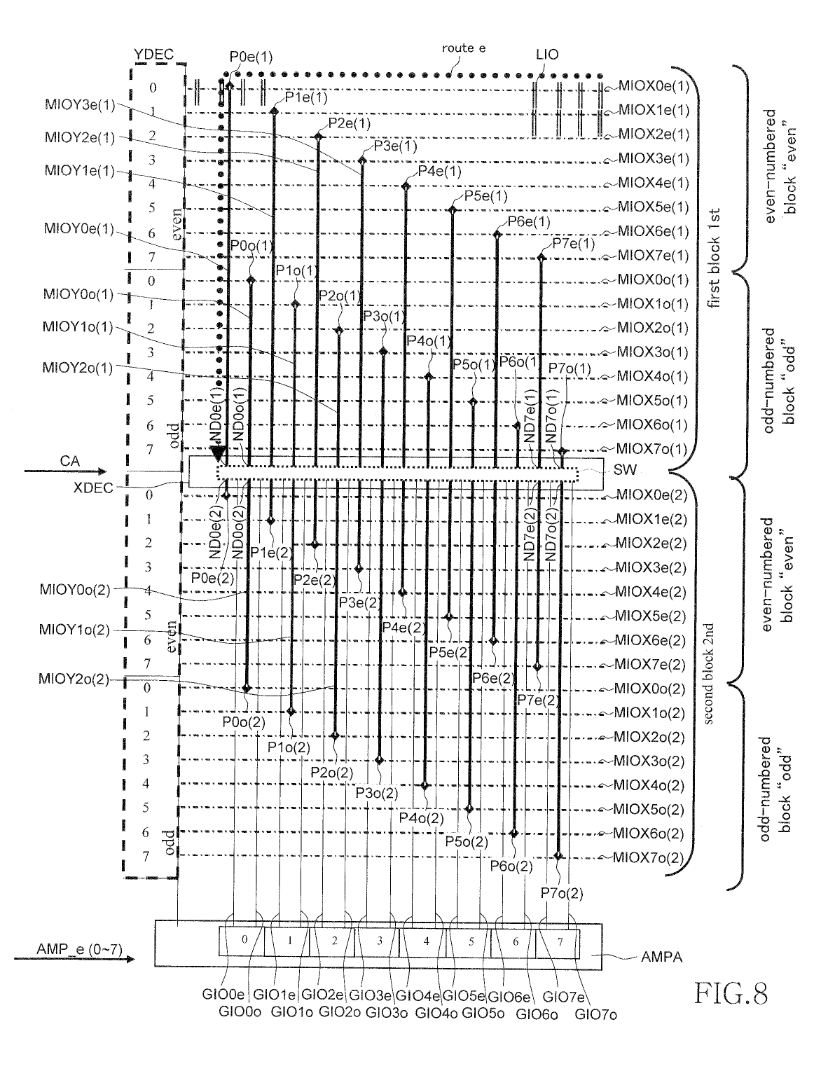

FIG. 8 is another plan view showing a layout of the comparative example.

In the example shown in FIG. 8, due to the arrangement that the second main I/O lines MIOY are arranged along from the end in order of wire length, the longest route that undergoes the first main I/O line MIOX0e furthest from the I/O node is a route “e” shown in FIG. 8, which is significantly longer than the route “d” shown in FIG. 7. This feature is identical to that of the first embodiment.

It is apparent that the present invention is not limited to the above embodiments, but may be modified and changed without departing from the scope and spirit of the invention.

What is claimed is:

1. A semiconductor memory device comprising:
a plurality of I/O nodes arranged along a first direction;
a plurality of first I/O lines arranged along a second direction substantially orthogonal to the first direction, each of the first I/O lines elongated along the first direction; and
a plurality of second I/O lines arranged along the first direction, each of the second I/O lines elongated along the second direction and connected between a corresponding one of the I/O nodes and a corresponding one of the first I/O lines,
wherein one of the second I/O lines, which is longest in the second I/O lines, is located substantially in a center of the corresponding first I/O line.

2. The semiconductor memory device as claimed in claim 1, wherein each of the rest of the second I/O lines is arranged between a center of the corresponding first I/O line and one end of the corresponding first I/O line.

3. The semiconductor memory device as claimed in claim 2, wherein a first group of the rest of the second I/O lines are arranged first side of the one of the second I/O lines and a second group of the rest of the second I/O lines are arranged second side of the one of the second I/O lines.

4. The semiconductor memory device as claimed in claim 3, wherein the first group includes n (n is an integer equal to or more than one) second I/O lines and the second group includes n+1 second I/O lines.

5. The semiconductor memory device as claimed in claim 1, wherein each of the first I/O lines is connected to one of a plurality of third I/O lines arranged along the first direction, each of the third I/O lines is elongated along the second direction.

6. The semiconductor memory device as claimed in claim 1, further comprising:
an even block and an odd block, each of the even block and the odd block having a plurality of memory cells, each of the memory cells in the even block is equal in address to a corresponding one of the memory cells in the odd block; and
an amplifier circuit area including a plurality of amplifier circuits provided respectively corresponding to one or more of the I/O nodes,
wherein each of the amplifier circuits has a first amplifier circuit connected to a corresponding one of the second I/O lines coupled to the even block and a second amplifier circuit connected to a corresponding one of the second I/O lines coupled to the odd second block.

7. The semiconductor memory device as claimed in claim 6, wherein one of the even block and the odd block and the other of the even block and the odd block are arranged along the second direction in this order, and the amplifier circuits are arranged along the first direction.

8. The semiconductor memory device as claimed in claim 1, wherein the I/O nodes are arranged between one of the even block and the odd block and the amplifier circuit area.

9. The semiconductor memory device as claimed in claim 6, wherein the even block has a first portion and a second portion, the first portion of the even block and the second portion of the even block are distinguished by a predetermined bit of a column address, the odd block has a first portion and a second portion, the first portion of the odd block and the second portion of the odd block are distinguished by the predetermined bit of the column address, and
the first portion of the even block and the first portion of the odd block are arranged adjacently and the second portion of the even block and the second portion of the odd block are arranged adjacently.

10. The semiconductor memory device as claimed in claim 9 wherein the first and second portions of the even block and the first and second portions of the odd block are arranged along the second direction.

11. The semiconductor memory device as claimed in claim 10, further comprising:
a first block including the first portions of the even and the odd blocks;
a second block including the second portion of the even and the odd blocks;
a switching circuit area arranged between the first block and the second block and having a plurality of switching circuits; and
a plurality of fourth I/O lines each connected between a corresponding one of the switching circuits and a corresponding one of the amplifier circuits,
wherein the I/O nodes are arranged in the switching circuit area.

12. The semiconductor memory device as claimed in claim 11, wherein each of the switching circuits connected to corresponding two of the second I/O lines, one of the corresponding two of the second I/O lines is located in the first block and the other of the corresponding two of the second I/O lines is located in the second block, each of the switching circuits select one of the corresponding two of the second I/O lines and connects the selected one of the corresponding two of the second I/O lines to a corresponding one of the forth I/O lines.

13. The semiconductor memory device as claimed in claim 11 wherein the fourth I/O lines are equal to one another in wire length.

14. A semiconductor memory device comprising:
N (N is an integer equal to or more than four) amplifier circuits that are arranged along a first direction and are respectively allocated with numbers of 0 to N−1 in order from an end;
N first I/O lines that are arranged along the second direction substantially orthogonal to the first direction and are allocated with numbers of 0 to N−1 corresponding to the N amplifier circuits, each of the N first I/O lines elongated along the first direction; and
N second I/O lines that are arranged along the first direction and are allocated with numbers of 0 to N−1 corresponding to the N amplifier circuits, each of the N second I/O lines connected between a corresponding one of the N first I/O lines and a corresponding one of the N amplifier circuits, connected to tie corresponding one of the N first I/O lines at a corresponding one of a plurality intersection points, the each of the N second I/O lines, the corresponding one of the N first I/O lines, the corresponding one of N amplifier circuits and the corresponding one of the intersection points allocated with a same number,
wherein intersection points allocated with 0 to (N/2)−1 are arranged along a third direction different from the first and second directions, and
intersection points allocated with N/2 to N−1 are arranged along a fourth direction different from the first to third directions.

15. The semiconductor memory device as claimed in claim 14, wherein an angle formed between a straight line extending in the first direction and a straight line extending in the third direction and an angle formed between the straight line extending in the first direction and a straight line extending in the fourth direction are substantially equal to each other.

16. A semiconductor memory device comprising:
a plurality of memory mats arranged in a matrix in first and second directions;
a plurality of sense amplifiers arranged in the second direction, each of the sense amplifiers arranged between corresponding ones of the memory mats;
a plurality of local I/O lines provided along the first direction, each of the local I/O lines elongated along the second direction and connected to a corresponding one of the sense amplifiers;
a plurality of first main I/O lines arranged along the second direction, each of the first main I/O lines elongated along the first direction and connected to a corresponding one of the local I/O lines;
a plurality of second main I/O lines arranged along the first direction, each of the second main I/O lines elongated along the second direction, one end of each of the second main I/O lines connected to a corresponding first main I/O lines, a plurality of I/O nodes each connected to a corresponding one of the second main I/O lines at the other end of the corresponding one of the second main I/O lines; and
a plurality of amplifier circuits each connected via a corresponding one of I/O node to a corresponding one of the second main I/O lines,
wherein one of the second main I/O lines, which is longest in the second main I/O lines, is located substantially in a center of the corresponding first main I/O line.

17. The semiconductor memory device as claimed in claim 16, further comprising a plurality of sub-word driver arrays each arranged between corresponding ones of the memory mats adjacent to the second direction and including a plurality of sub-word drivers,
wherein the sub-word driver arrays are connected correspondingly to a plurality of sub-word lines extending along the second direction, and
the sense amplifier arrays are connected correspondingly to a plurality of bit lines extending along the first direction.

18. The semiconductor memory device as claimed in claim 16, wherein ones of the local I/O lines connected to one of the first main I/O lines are arranged at a substantially equal interval in the first direction.

19. The semiconductor memory device as claimed in claim 16, wherein each of the rest of the second main I/O lines is arranged between a center of the corresponding first I/O line and one end of the corresponding first I/O line.

20. The semiconductor memory device as claimed in claim 19, wherein a first group of the rest of the second main I/O lines are arranged first side of the one of the second main I/O lines and a second group of the rest of the second main I/O lines are arranged second side of the one of the second main I/O lines.
